(19) United States
(12) Patent Application Publication
(10) Pub. No.: US 2013/0044557 A1
(43) Pub. Date: Feb. 21, 2013

(54) MEMORY CONTROL METHOD OF MEMORY DEVICE AND MEMORY CONTROL SYSTEM THEREOF

(71) Applicant: MEDIATEK INC., Hsin-chu (TW)

(72) Inventors: Kun-Bin Lee, Taipei City (TW); Shao-Kuang Lee, Miaoli County (TW)

(73) Assignee: MEDIATEK INC., Hsin-Chu (TW)

(21) Appl. No.: 13/658,837

(22) Filed: Oct. 24, 2012

Related U.S. Application Data
(62) Division of application No. 12/429,186, filed on Apr. 24, 2009, now abandoned.

(51) Int. Cl. G11C 7/00

(52) U.S. Cl. 365/222

(57) ABSTRACT

One exemplary memory control method of a memory device includes: assigning an indicator to each physical row partition in the memory device for indicating if the corresponding physical row partition is to be refreshed; and controlling a partial refresh operation of the memory device according to the indicator of each physical row partition. Each physical row partition is a portion of the memory device. Another exemplary memory control system of a memory device, comprising: a checking unit configured for setting at least one indicator to indicate if part of the memory device is to be refreshed by a partial refresh operation; and a refresh control unit configured for controlling the memory device to perform the partial refresh operation according to the at least one indicator.

### CROSS REFERENCE TO RELATED APPLICATIONS

The present application is a divisional application of U.S. patent application Ser. No. 12/429,186, which was filed on Apr. 24, 2009. The entire contents of the related application are incorporated herein by reference.

### BACKGROUND

The present invention relates to controlling a memory device, and more particularly, to a memory control method and memory control system of a memory device (e.g., a dynamic random access memory) for applying a partition-based partial bank interleaving and a partial refresh (e.g., a partial array self refresh) upon a memory device to take advantage of low power features of the memory device without degrading the access performance of the memory device.

Memory devices are indispensable to electronic apparatuses. In general, the memory devices can be categorized into volatile memory devices and non-volatile memory devices. Dynamic random access memory (DRAM) is one type of the volatile memory, and is the most common and least expensive memory due to its simplicity in structure. That is, DRAM is based on a capacitor's ability to hold charges and requires only one transistor per bit. This allows DRAM to reach very high density. However, since real capacitor leaks charge stored therein, the stored information eventually fades unless the capacitor is refreshed periodically.

FIG. 1 shows a simplified architecture of a conventional DRAM device. The DRAM device 100 includes a plurality of memory banks (memory arrays) 102_1-102_N, a bank decoder 104, a plurality of row decoders 106_1-106_N respectively corresponding to the memory banks 102_1-102_N, and a plurality of column decoders 108_1-108_N respectively corresponding to the memory banks 102_1-102_N. The bank decoder 104 decodes a bank address BA generated from a memory controller (not shown) to select a target memory bank (e.g., 102_1) requested for reading or writing desired data. The row decoder (e.g., 106_1) decoders the row address RA generated from the memory controller to select a row in the target memory bank 102_1, where a memory cell containing the requested data bit is located in the selected row. The column decoder (e.g., 108_1) decoders the column CA generated from the memory controller to select a column in the target memory bank 102_1, where the memory cell containing the requested data bit to be read or the memory cell requested for writing data bit is located in the selected column.

However, regarding different DRAM status of a memory access, the conventional memory controller needs to issue different commands to the DRAM device 100, leading to different access latency. For example, when the memory controller accesses the DRAM device 100, the DRAM device 100 might have one of the following DRAM statuses: “Page Hit”, “Bank Miss”, and “Row Miss”. The “Page Hit” status means that the addressed memory bank is in an active state, and the row address of an activated row in the addressed memory bank is the same as that of the incoming memory access. Hence, column-access commands (read/write commands) can be directly issued by the memory controller. The “Bank Miss” status means that an incoming memory access is addressed to a memory bank in an idle state. Therefore, the memory controller has to activate the target row in the addressed memory bank first, and then issues the column-access commands. The “Row Miss” status means that the addressed memory bank is in an active state, and the row address of an activated row in the addressed memory bank is different from that of the incoming memory access. Therefore, the memory controller has to precharge the addressed memory bank, then activate the target row, and finally issue column-access commands.

The access time required for accessing data in the DRAM device 100 with the “Page Hit” status is shorter than that required for accessing data in the DRAM device 100 with the “Bank Miss” status, and the access time required for accessing data in the DRAM device 100 with the “Bank Miss” status is shorter than that required for accessing data in the DRAM device 100 with the “Page Miss” status. In other words, regarding the memory access of the DRAM device 100 with the “Page Miss” status, the access performance would be seriously degraded due to the significant access latency. To improve the access performance, a conventional bank interleaving access method is widely utilized. FIG. 2 is a diagram illustrating a conventional full bank interleaving applied to a memory device. The conventional full bank interleaving can be easily achieved by swapping the bank address and least significant bits (LSBs) of the row address. For example, the memory device as shown in FIG. 2 has four memory banks, and each memory bank has four rows. Therefore, each memory bank is originally addressed by a bank address including two bits B1 and B0, and each row is originally addressed by a row address including two bits R1 and R0. The conventional full bank interleaving would generate a remapped memory address by swapping the bank address and the row address. Therefore, each virtual row is addressed by a bank address including two bits R1 and R0, and a row address including two bits B1 and B0. As a result, the physical rows 0-3 in the physical bank 0 are mapped to virtual rows addressed by the remapped memory addresses: (Bank 0, Row 0), (Bank 1, Row 0), (Bank 2, Row 0), and (Bank 3, Row 0); the physical rows 0-3 in the physical bank 1 are mapped to virtual rows addressed by the remapped memory addresses: (Bank 0, Row 1), (Bank 1, Row 1), (Bank 2, Row 1), and (Bank 3, Row 1); the physical rows 0-3 in the physical bank 2 are mapped to virtual rows addressed by the remapped memory addresses: (Bank 0, Row 2), (Bank 1, Row 2), (Bank 2, Row 2), and (Bank 3, Row 2); and the physical rows 0-3 in the physical bank 3 are mapped to virtual rows addressed by the remapped memory addresses: (Bank 0, Row 3), (Bank 1, Row 3), (Bank 2, Row 3), and (Bank 3, Row 3). In other words, a plurality of virtual page each having the same row from different memory banks are created using the conventional full bank interleaving method.

As known to those skilled in the art, the DRAM requires a refresh operation performed periodically to keep the stored data. However, some of the memory cells might not store valid data, and therefore do not need to be refreshed for keeping the data stored therein. If all of the memory cells in the DRAM device are refreshed periodically, power consumption of the overall system is inevitably increased. Therefore, a low power feature called Partial Array Self Refresh (PASR) is developed to enable the DRAM to retain state in only part of the memory, thus further reducing the refresh power consumption. In general, the PASR schemes can be categorized into three types: single ended PASR shown in FIG. 3, dual ended PASR shown in FIG. 4, and bank selective PASR shown in FIG. 5. The selection of banks to be refreshed is based on the PASR scheme employed by the DRAM device. Therefore, to achieve the optimized performance of reducing the refresh power consumption, the memory management scheme used for storing data in the memory and the PASR scheme used for refreshing data stored in the memory have to work in coordination. More specifically, different applications may employ different memory management schemes for storing data in the memory. Therefore, different PASR schemes are devised to meet the requirements of these memory management schemes. In other words, the DRAM device is configured to use one of the available PASR schemes to meet the requirement of a target application which employs a specific memory management scheme for storing data in the memory. In FIG. 3-FIG. 5, the memory banks marked by oblique lines are selected and refreshed using the conventional PASR operation. Regarding the single ended PASR scheme, data are stored into the DRAM device in one direction from the lowest memory address to the highest memory address (i.e., from the memory bank 0 to the memory bank 3 as indicated in FIG. 3), and only the memory banks which store valid data will be selected and refreshed. Regarding the dual ended PASR scheme, data are stored into the DRAM device in opposite directions as indicated in FIG. 4, and only the memory banks which store valid data will be selected and refreshed. Regarding the bank selective PASR scheme, each memory bank is independently marked to be self refreshed, and only the memory banks which store valid data will be selected and refreshed; thus, any combination of memory banks can be self refreshed. Compared to the single ended PASR model, both the dual ended and bank selective PASR models are OS-friendly. In addition, the memory controller will program a PASR Extended Mode Register in the DRAM device to define which one of full array mode, ½ array mode, ¼ array mode, ⅛ array mode, and 1/16 array mode is enabled when the DRAM device is self-refreshed using a selected PASR scheme (i.e., single ended PASR scheme, dual ended PASR scheme, or bank selective PASR scheme).

In a case where no bank interleaving is implemented, if the valid data to be kept are only allocated in one memory bank, say, bank 0, only memory cells included in the memory bank are needed to be refreshed during a low power mode (i.e., a self refresh mode) by using ¼ or ⅛ PASR. However, in another case where bank interleaving is implemented, if the valid data to be kept are stored into memory addresses including the same bank address, say, bank 0, the data addressed by memory addresses, such as (Bank 0, Row 0), (Bank 0, Row 1), (Bank 0, Row 2), and (Bank 0, Row 3), are stored into different physical banks due to bank interleaving. As a result, though the conventional full bank interleaving technique is able to improve the access performance, but has difficulty in taking advantage of the PASR operation.

Thus, there is a need for a novel bank interleaving scheme which is capable of taking advantage of DRAM low power features and having improved DRAM access performance.

### SUMMARY

In one exemplary embodiment of the present invention, a partition-based partial bank interleaving and a partial refresh (e.g., a partial array self refresh) are applied to a memory device to take advantage of low power features of the memory device and improve access performance of the memory device.

According to a first aspect of the present invention, a memory control method of a memory device is provided. The memory control method includes: determining at least a physical row partition including a plurality of physical rows selected from the memory device, wherein each physical row partition is a portion of the memory device; and for each physical row partition, mapping interleaved virtual rows to the selected physical rows. Bank addresses of adjacent virtual rows are different.

According to a second aspect of the present invention, a memory control method of a memory device is provided. The memory control method includes: setting at least one indicator to indicate if part of the memory device is to be refreshed by a partial refresh operation; and controlling the memory device to perform the partial refresh operation according to the at least one indicator. In one exemplary example, the memory control method further comprising: determining at least a physical row partition including a plurality of physical rows selected from the memory device, wherein each physical row partition is a portion of the memory device; and for each physical row partition, mapping interleaved virtual rows to the selected physical rows, wherein bank addresses of adjacent virtual rows are different.

According to a third aspect of the present invention, a memory control system of a memory device is provided. The memory control system includes a determining unit and a mapping unit. The determining unit is configured for determining at least a physical row partition including a plurality of physical rows selected from the memory device, wherein each physical row partition is a portion of the memory device. The mapping unit is coupled to the determining unit. For each physical row partition, the mapping unit maps interleaved virtual rows to the selected physical rows. Bank addresses of adjacent virtual rows are different.

According to a fourth aspect of the present invention, a memory control system of a memory device is provided. The memory control system includes a checking unit and a refresh control unit. The checking unit is configured for setting at least one indicator to indicate if part of the memory device is to be refreshed by a partial refresh operation. The refresh control unit is configured for controlling the memory device to perform the partial refresh operation according to the at least one indicator. In one exemplary example, the memory control system further comprising: a determining unit, determining at least a physical row partition including a plurality of physical rows selected from the memory device, wherein each physical row partition is a portion of the memory device; and a mapping unit, for each physical row partition, mapping interleaved virtual rows to the selected physical rows, wherein bank addresses of adjacent virtual rows are different.

[001 5] These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a simplified architecture of a conventional DRAM device.

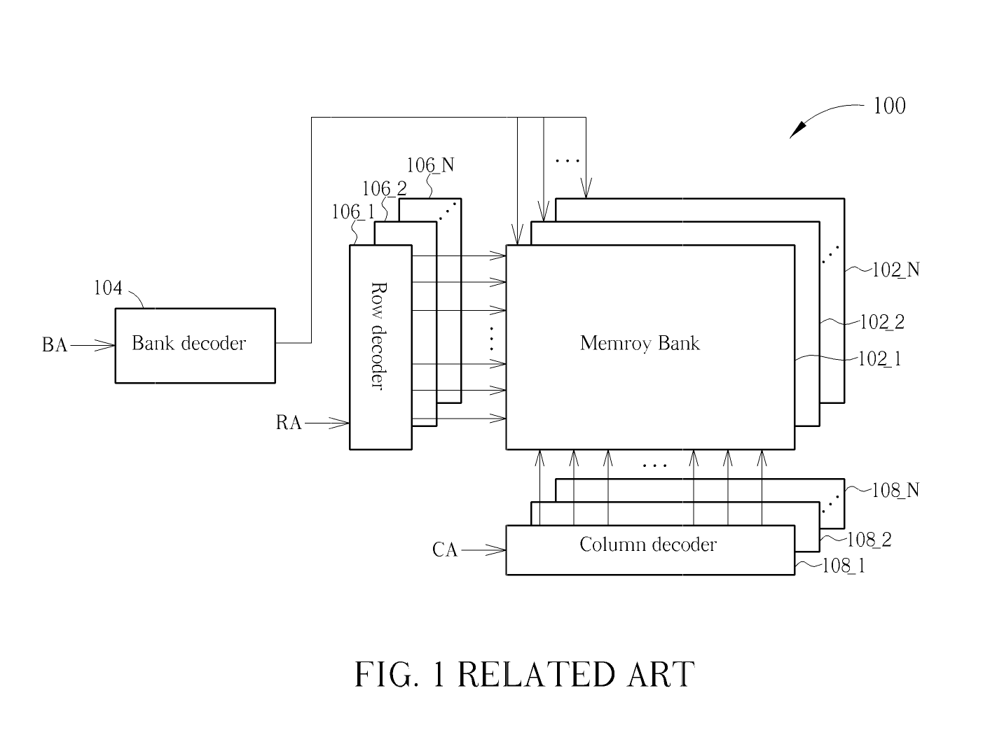

FIG. 2 is a diagram illustrating a conventional full bank interleaving applied to a memory device.

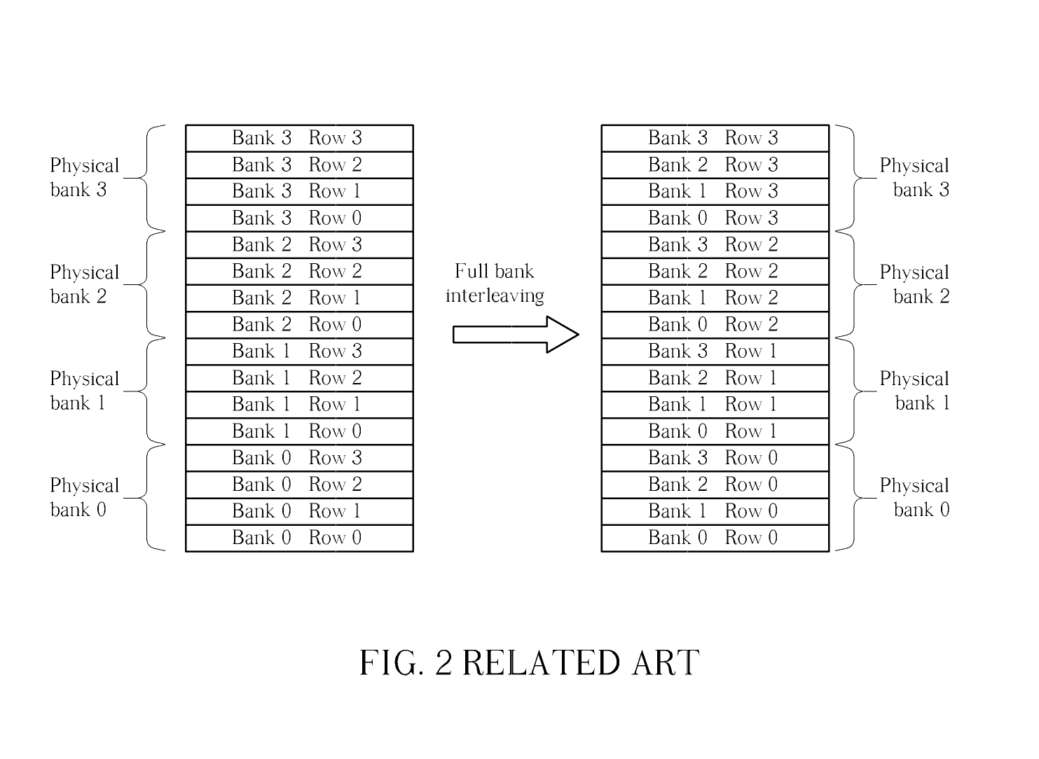

FIG. 3 is a diagram illustrating a conventional single ended PASR scheme.

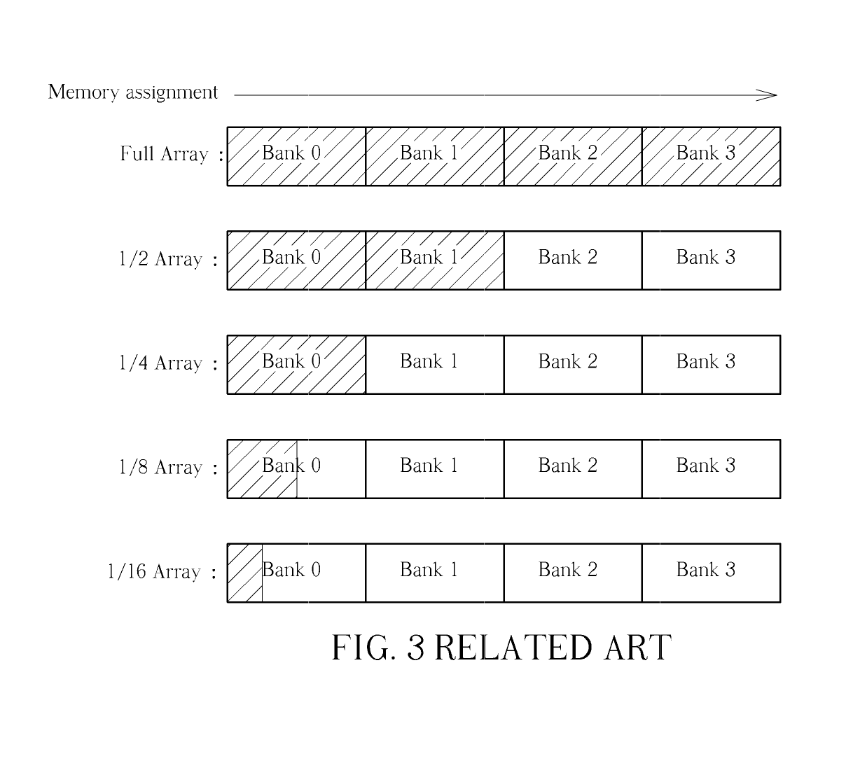

FIG. 4 is a diagram illustrating a conventional dual ended PASR scheme.

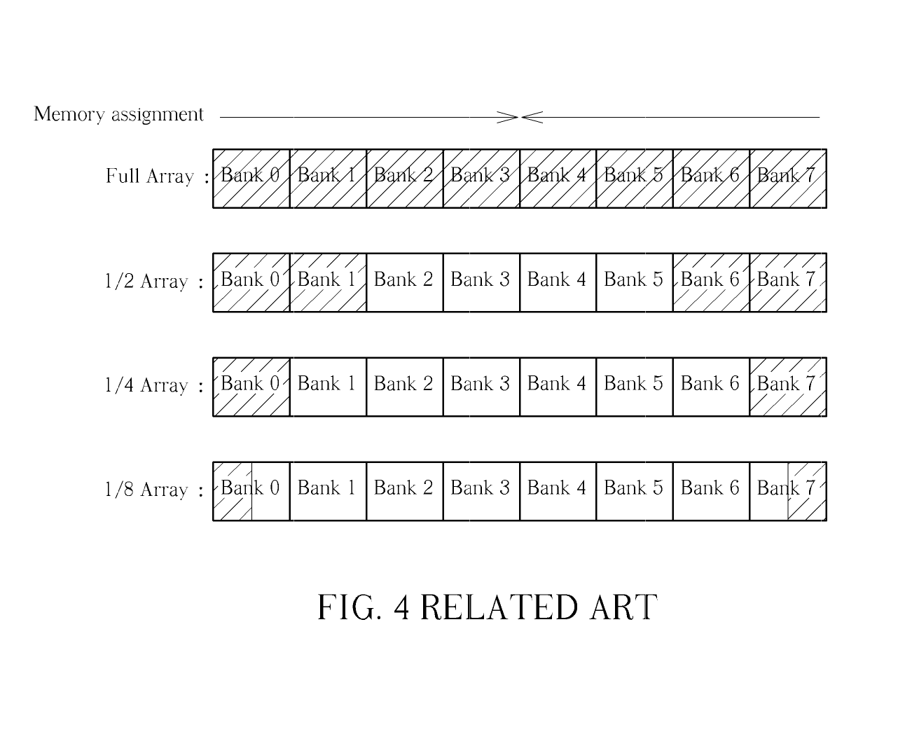

FIG. 5 is a diagram illustrating a conventional bank selective PASR scheme.

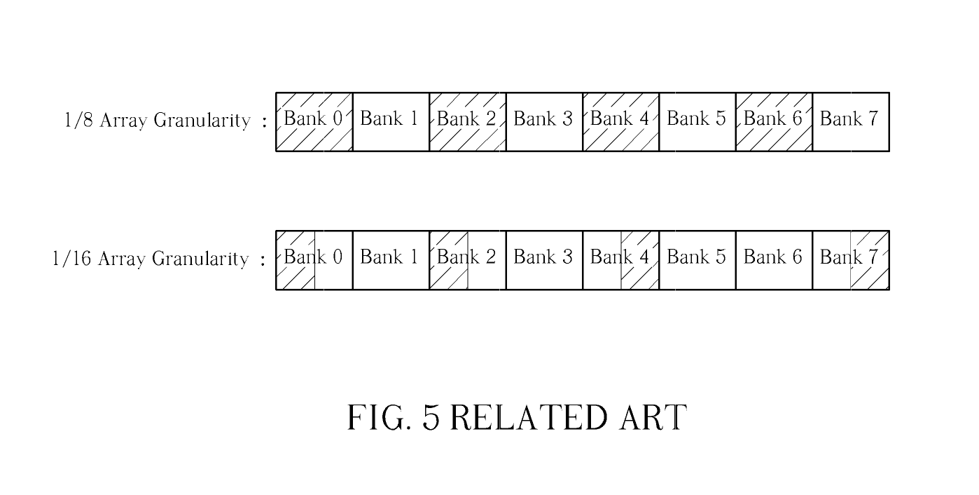

FIG. 6 is a block diagram illustrating a memory control system according to an exemplary embodiment of the present invention.

FIG. 7 is a diagram illustrating a first exemplary implementation of the partition-based partial bank interleaving according to the present invention.

FIG. 8 is a diagram illustrating a second exemplary implementation of the partition-based partial bank interleaving according to the present invention.

FIG. 9 is a diagram illustrating a third exemplary implementation of the partition-based partial bank interleaving according to the present invention.

FIG. 10 is a flowchart illustrating a generalized memory control method of a memory device according to an exemplary embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

The conception of the present invention is to apply a partition-based partial bank interleaving and a partial refresh (e.g., PASR) to a memory device (e.g., a DRAM device) for taking advantage of low power features of the memory device and improving the access performance of the memory device. Details of the present invention are illustrated using following exemplary embodiments.

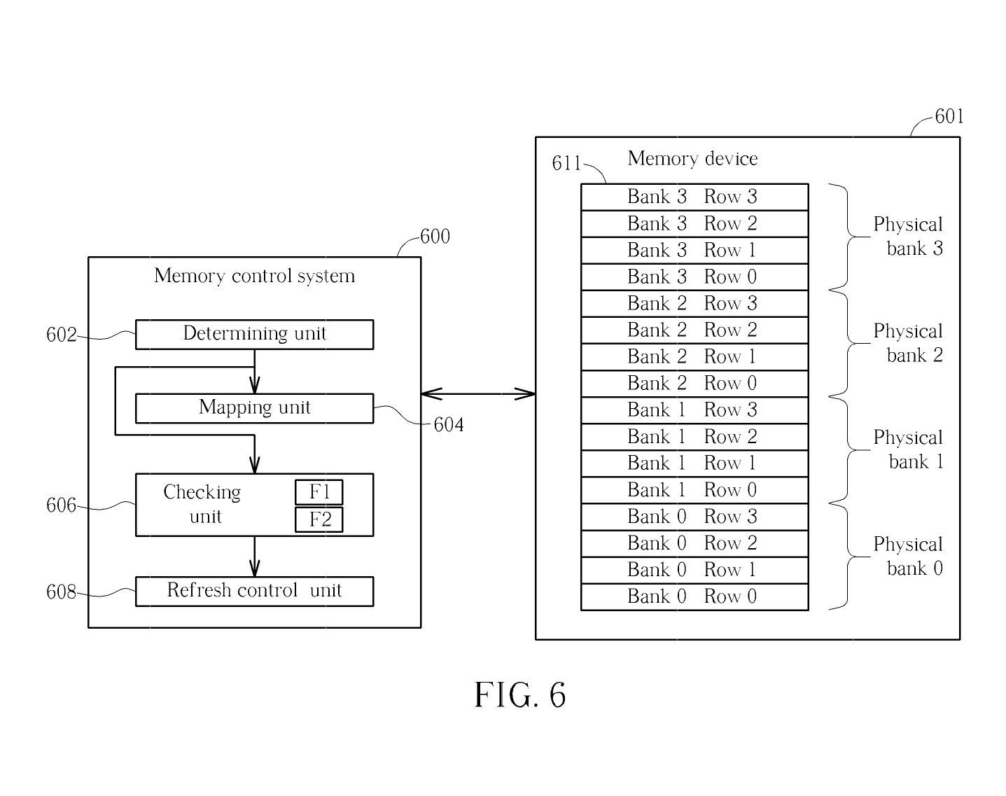

FIG. 6 is a block diagram illustrating a memory control system according to an exemplary embodiment of the present invention. The memory control system 600 is used to control data access and refresh of a memory device (e.g., a DRAM device) 601 which includes a plurality of physical rows 611. In this exemplary embodiment, the memory control system 600 includes, but is not limited to, a determining unit 602, a mapping unit 604, a checking unit 606, and a refresh control unit 608. The determining unit 602 is configured for determining at least a physical row partition including a plurality of physical rows selected from the memory device 601, wherein each physical row partition is a portion of the memory device 601. For example, the memory device 601 includes four physical banks each having four physical rows. In one implementation, the determining unit 602 determines a first physical row partition and a second physical row partition according to physical rows 611 in the memory device 601, wherein the first physical row partition includes physical rows defined to be physically addressed by (Bank 0, Row 0), (Bank 0, Row 1), (Bank 0, Row 2), (Bank 0, Row 3), (Bank 1, Row 0), (Bank 1, Row 1), (Bank 1, Row 2), and (Bank 1, Row 3), and the second physical row partition includes physical rows defined to be physically addressed by (Bank 2, Row 0), (Bank 2, Row 1), (Bank 2, Row 2), (Bank 2, Row 3), (Bank 3, Row 0), (Bank 3, Row 1), (Bank 3, Row 2), and (Bank 3, Row 3).

The mapping unit 604 is coupled to the determining unit 602, and is configured for mapping a plurality of interleaved virtual rows to selected physical rows included in each physical row partition determined by the determining unit 602. Besides, bank addresses of adjacent virtual rows are different. Certain exemplary implementations of a partition-based partial bank interleaving controlled by the mapping unit 604 are illustrated as follows.

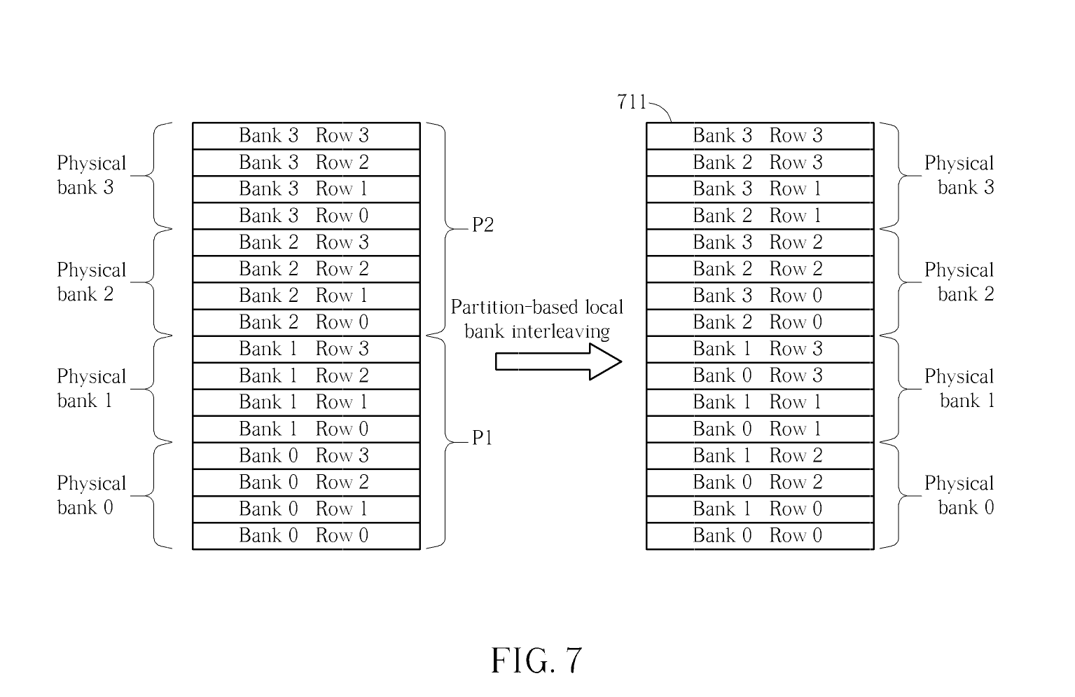

FIG. 7 is a diagram illustrating a first exemplary implementation of the partition-based partial bank interleaving according to the present invention. In this exemplary implementation, the determining unit 602 determines a first physical row partition P1 and a second physical row partition P2. Regarding the first physical row partition P1, the mapping unit 604 maps a plurality of interleaved virtual rows 711 addressed by (Bank 0, Row 0), (Bank 1, Row 0), (Bank 0, Row 2), (Bank 1, Row 2), (Bank 0, Row 1), (Bank 1, Row 1), (Bank 0, Row 3), and (Bank 1, Row 3) to selected physical rows (Bank 0, Row 0), (Bank 0, Row 1), (Bank 0, Row 2), (Bank 0, Row 3), (Bank 1, Row 0), (Bank 1, Row 1), (Bank 1, Row 2), and (Bank 1, Row 3), respectively. Regarding the second physical row partition P2, the mapping unit 604 maps a plurality of interleaved virtual rows 711 addressed by (Bank 2, Row 0), (Bank 3, Row 0), (Bank 2, Row 2), (Bank 3, Row 2), (Bank 2, Row 1), (Bank 3, Row 1), (Bank 2, Row 3), and (Bank 3, Row 3) to selected physical rows (Bank 2, Row 0), (Bank 2, Row 1), (Bank 2, Row 2), (Bank 2, Row 3), (Bank 3, Row 0), (Bank 3, Row 1), (Bank 3, Row 2), and (Bank 3, Row 3), respectively. The mapping unit 604 performs the above-mentioned mapping between the physical rows and virtual rows by generating remapped addresses. For example, the example in FIG. 7 shows that four memory banks are included in a memory device, and each memory bank has four rows. Therefore, each memory bank is originally addressed by a bank address including two bits B1 and B0, and each row is originally addressed by a row address including two bits R1 and R0. The mapping unit 604 would generate a remapped memory address by swapping at least one bit of the bank address and the row address. Therefore, each virtual row is addressed by a bank address including two bits B1 and R0, and a row address including two bits R1 and B0. For instance, data to be read from or written into a physical row addressed by (Bank 0, Row 3) would be directed to accessing a physical row addressed by (Bank 1, Row 2) which is now mapped to a virtual row addressed by (Bank 0, Row 3). That is, in each physical row partition determined by the determining unit 602, each of bank addresses of the interleaved virtual rows is selected from bank addresses of the selected physical rows, and the bank addresses of the selected physical rows correspond to consecutive physical banks of the memory device 601. The bank interleaving result shown in FIG. 7 is applicable to a single ended PASR memory device. However, this is not meant to be a limitation to the scope of the present invention. That is, any PASR memory device using the exemplary partition-based partial bank interleaving shown in FIG. 7 obeys the spirit of the present invention. As the memory rows are not interleaved using conventional full bank interleaving mentioned above, the memory device can benefit from the PASR scheme. Besides, due to the memory rows are still interleaved using the proposed partition-based partial bank interleaving, the access performance of the memory device is still improved.

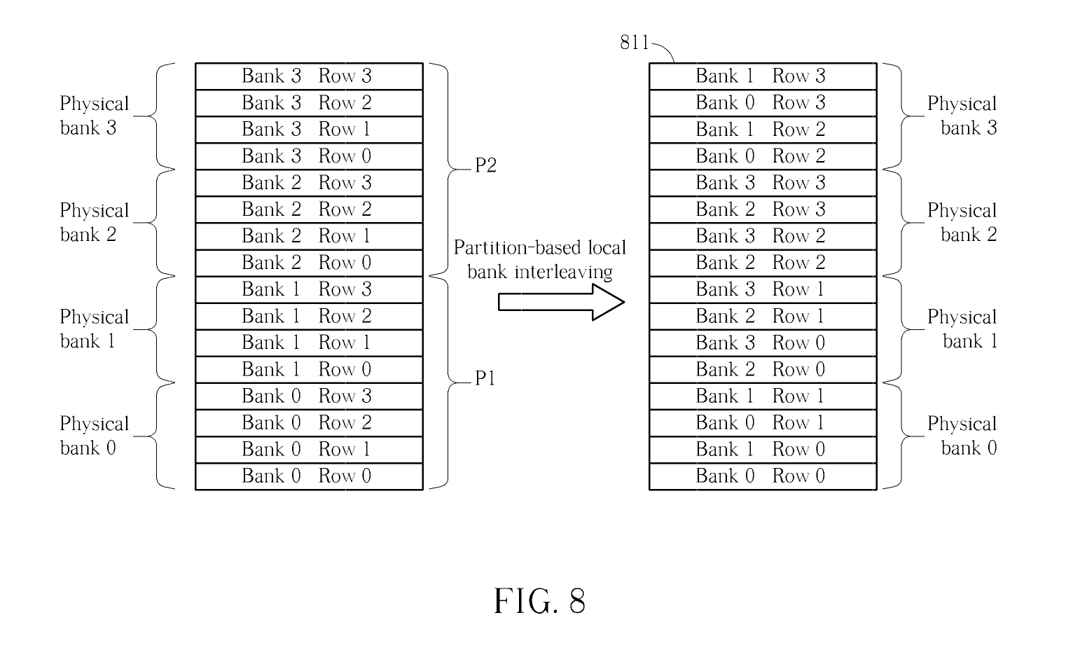

FIG. 8 is a diagram illustrating a second exemplary implementation of the partition-based partial bank interleaving according to the present invention. In this exemplary implementation, the determining unit 602 determines a first physical row partition P1 and a second physical row partition P2. Regarding the first physical row partition P1, the mapping unit 604 maps a plurality of interleaved virtual rows 811 addressed by (Bank 0, Row 0), (Bank 1, Row 0), (Bank 0, Row 1), (Bank 1, Row 1), (Bank 2, Row 0), (Bank 3, Row 0), (Bank 2, Row 1), and (Bank 3, Row 1) to selected physical rows (Bank 0, Row 0), (Bank 0, Row 1), (Bank 0, Row 2), (Bank 0, Row 3), (Bank 1, Row 0), (Bank 1, Row 1), (Bank 1, Row 2), and (Bank 1, Row 3), respectively. Regarding the second physical row partition P2, the mapping unit 604 maps a plurality of interleaved virtual rows 811 addressed by (Bank 2, Row 2), (Bank 3, Row 2), (Bank 2, Row 3), (Bank 3, Row 3), (Bank 0, Row 2), (Bank 1, Row 2), (Bank 0, Row 3), and (Bank 1, Row 3) to selected physical rows (Bank 2, Row 0), (Bank 2, Row 1), (Bank 2, Row 2), (Bank 2, Row 3), (Bank 3, Row 0), (Bank 3, Row 1), (Bank 3, Row 2), and (Bank 3, Row 3), respectively. Similarly, the mapping unit 604 performs the above-mentioned mapping between the physical rows and virtual rows by generating remapped addresses. In this exemplary implementation, an XOR logic operation is involved in generating remapped addresses. For example, the example in FIG. 8 shows that four memory banks are included in a memory device, and each memory bank has four rows. Therefore, each memory bank is originally addressed by a bank address including two bits B1 and B0, and each row is originally addressed by a row address including two bits R1 and R0. The mapping unit 604 would generate a remapped memory address by making each virtual row addressed by a bank address including two bits (B0 XOR B1) and R0, and a row address including two bits B1 and B0. For instance, data to be read from or write into a physical row addressed by (Bank 0, Row 3) would be directed to accessing a physical row addressed by (Bank 3, Row 2) which is mapped to a virtual row addressed by (Bank 0, Row 3). That is, bank addresses of the interleaved virtual rows, mapped to selected physical rows included in each physical row partition determined by the determining unit 602, include at least one bank address different from bank addresses of the selected physical rows. The bank interleaving result shown in FIG. 8 is applicable to a dual ended PASR memory device. However, this is not meant to be a limitation to the scope of the present invention. That is, any PASR memory device using the exemplary partition-based partial bank interleaving shown in FIG. 8 obeys the spirit of the present invention. As the memory rows are not interleaved using conventional full bank interleaving mentioned above, the memory device can benefit from the PASR scheme. Besides, due to the memory rows are still interleaved using the proposed partition-based partial bank interleaving, the access performance is still improved.

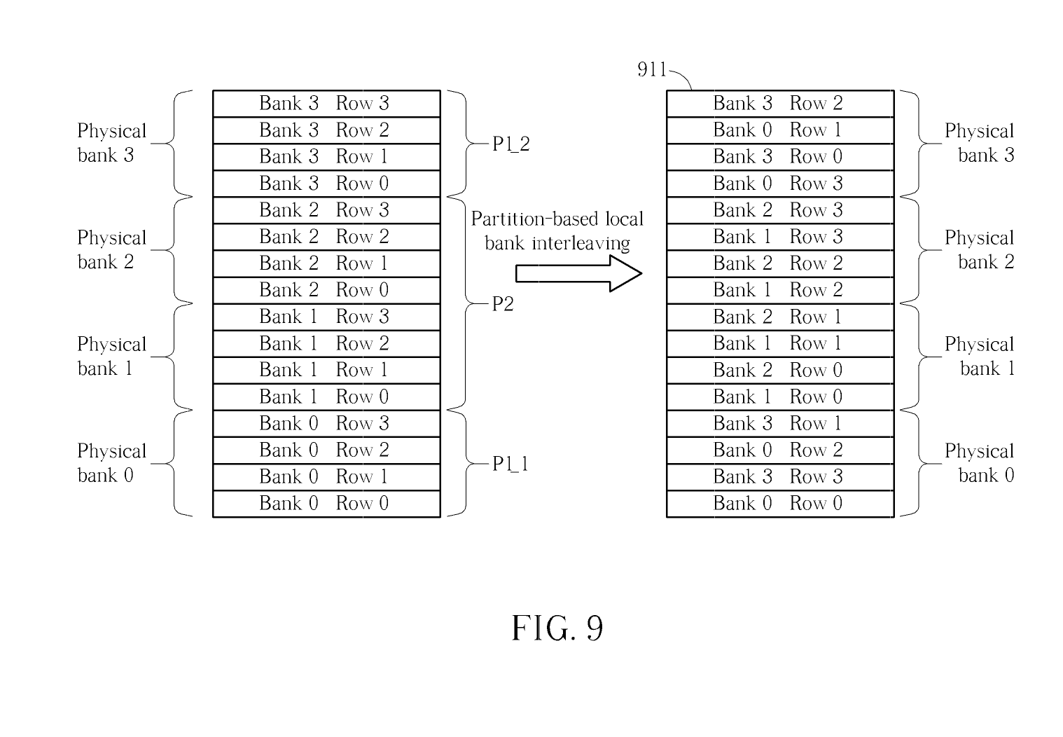

FIG. 9 is a diagram illustrating a third exemplary implementation of the partition-based partial bank interleaving according to the present invention. In this exemplary implementation, the determining unit 602 determines a first physical row partition P1 consisting of sub-partitions P1_1 and P1_2 and a second physical row partition P2. Regarding the first physical row partition P1, the mapping unit 604 maps a plurality of interleaved virtual rows 911 addressed by (Bank 0, Row 0), (Bank 3, Row 3), (Bank 0, Row 2), (Bank 3, Row 1), (Bank 0, Row 3), (Bank 3, Row 0), (Bank 0, Row 1), and (Bank 3, Row 2) to selected physical rows (Bank 0, Row 0), (Bank 0, Row 1), (Bank 0, Row 2), (Bank 0, Row 3), (Bank 3, Row 0), (Bank 3, Row 1), (Bank 3, Row 2), and (Bank 3, Row 3), respectively. Regarding the second physical row partition P2, the mapping unit 604 maps a plurality of interleaved virtual rows 911 addressed by (Bank 1, Row 0), (Bank 2, Row 0), (Bank 1, Row 1), (Bank 2, Row 1), (Bank 1, Row 2), (Bank 2, Row 2), (Bank 1, Row 3), and (Bank 2, Row 3) to selected physical rows (Bank 1, Row 0), (Bank 1, Row 1), (Bank 1, Row 2), (Bank 1, Row 3), (Bank 2, Row 0), (Bank 2, Row 1), (Bank 2, Row 2), and (Bank 2, Row 3), respectively. Similarly, the mapping unit 604 performs the above-mentioned mapping between the physical rows and virtual rows by generating remapped addresses. With regard to this exemplary implementation, in each physical row partition determined by the determining unit 602, each of bank addresses of the interleaved virtual rows is selected from bank addresses of the selected physical rows, and the bank addresses of the selected physical rows correspond to non-consecutive physical banks of the memory device 601. As the bank interleaving result shown in FIG. 9 is more similar to the memory assignment behavior of an operating system, the partition-based partial bank interleaving scheme of FIG. 9 is preferable to the partition-based partial bank interleaving scheme of FIG. 8 for the dual ended PASR memory device. However, this is not meant to be a limitation to the scope of the present invention. That is, any PASR memory device using the exemplary partition-based partial bank interleaving shown in FIG. 9 obeys the spirit of the present invention. As the memory rows are not interleaved using conventional full bank interleaving mentioned above, the memory device can benefit from the PASR scheme. Besides, due to the memory rows are still interleaved using the proposed partition-based partial bank interleaving, the access performance is still improved.

In the present invention, the memory address mapping design for the partition-based partial bank interleaving is selected according to a PASR scheme applied to the memory device 601. For example, when the single ended PASR hardware model is employed, the partition-based partial bank interleaving scheme shown in FIG. 7 is adopted; when the dual ended PASR hardware model is employed, the partition-based partial bank interleaving scheme shown in FIG. 8 or FIG. 9 is adopted; and when the bank selective PASR hardware model is employed, any of the partition-based partial bank interleaving schemes shown in FIG. 7-FIG. 9 can be adopted as the partition-based partial bank interleaving schemes shown in FIG. 7-FIG. 9 are all better than the conventional full-bank interleaving scheme. Please note that the mapping between the physical rows and the virtual rows, as shown in FIG. 7-FIG. 9, are for illustrative purposes only. Other alternative memory address mapping designs for the partition-based partial bank interleaving are feasible as long as bank addresses of adjacent virtual rows mapped to physical rows in the same physical row partition are different. In addition, the afore-mentioned memory address mapping performed by the mapping unit 604 can be realized using hardware, software, or a combination thereof. More specifically, provided that the same objective is achieved, the components of the memory control system 600 can be implemented using hardware, software, or a combination thereof, depending upon design requirements. These alternative designs also fall within the scope of the present invention.

In addition to setting the memory address mapping for the partition-based partial bank interleaving, the memory control system 600 is also responsible for controlling the refresh operation applied to the memory device 601 which is a DRAM device in one exemplary embodiment of the present invention. The checking unit 606 in the memory control system 600 is configured for assigning an indicator (e.g., a flag) to each physical row partition determined by the determining unit 602 for indicating if the corresponding physical row partition should be refreshed. As mentioned above, each physical row partition determined by the determining unit 602 is only a portion of the memory device 601. For instance, regarding the physical row partitions P1 and P2 shown in FIG. 7-FIG. 9, the checking unit 606 assigns indicators, such as flags F1 and F2, to the two physical row partitions P1 and P2 determined by the determining unit 602, respectively. In this exemplary embodiment, the checking unit 606 decides which physical row partition should be refreshed to generate a checking result, and then asserts/deasserts the flags F1 and F2 according to the checking result. It should be noted that the flags can be implemented using either hardware or software.

More specifically, the checking unit 606 determines a free physical memory map of the memory device 601 to decide which physical row partition should be refreshed. In a case where the memory system, including the memory control system 600 and the memory device 601, is applied to a deeply embedded system (e.g., an optical disc player) requiring no memory management unit (MMU) generally used for performing virtual address translations, the checking unit 606 can easily obtain a memory usage map of the memory device 601 as the memory allocations of tasks to be handled by the deeply embedded system are well pre-defined. After the memory usage map is obtained, the memory locations in which valid data are currently stored can be easily derived. Therefore, the checking unit 606 knows which region of data in the memory device 601 needs to be kept (refreshed) during a low power mode (i.e., a self refresh mode), and then decides a memory maintenance map accordingly. In one exemplary embodiment of the present invention, the memory maintenance map is simply realized using the aforementioned flags. Take the bank interleaving result shown in FIG. 7 as an example. If the checking unit 606 refers to the memory usage map to know that the memory device 601 only has valid data stored in virtual rows addressed by (Bank 0, Row 0), (Bank 0, Row 1), (Bank 0, Row 2) and (Bank 0, Row 3), the checking unit 606 determines the memory maintenance map (e.g., flags F1 and F2) which indicates that the physical row partition P1 should be refreshed during the low power mode due to valid data stored therein, and the other physical row partition P2 is not required to be refreshed during the low power mode due to invalid data stored therein. Therefore, the flag F1 corresponding to the physical row partition P1 is asserted, while the flag F2 corresponding to the physical row partition P2 is deasserted. Next, the refresh control unit 608 controls a refresh operation of the memory device 601 according to the memory maintenance map which includes flags F1 and F2. For example, the refresh control unit 608 sets proper values into the PASR Extended Mode Register in the memory device 601 to define which one of full array mode, ½array mode, ¼ array mode, ⅛ array mode, and 1/16 array mode is enabled when the memory device 601 is self-refreshed in the low power mode. As a result, the refresh operation only refreshes the physical rows included in the physical row partition P1 to achieve the objective of reducing the refresh power consumption.

In another case where the memory system, including the memory control system 600 and the memory device 601, is applied to a system running a powerful operating system (e.g., Windows Mobile or Linux) which requires a memory management unit (MMU) for performing virtual address translations, the checking unit 606 cannot directly obtain a memory usage map of the memory device 601 as the memory allocations of tasks to be handled by the operating system are dynamically allocated. In this exemplary embodiment, the checking unit 606 refers to information maintained by the operating system to determine the free physical memory map, thereby obtaining the desired memory usage map. Taking the Linux operation system for example, it stores all the information about memory usage in three zones: DMA, Normal, and Highmem. Each zone has a list of free memory regions. As memory areas falling outside of these free memory regions are used, the checking unit 606 therefore can obtain a memory usage map of the memory device 601 according to the free physical memory map derived from the lists of free memory regions. After the memory usage map is obtained, the memory locations in which valid data are currently stored can be easily derived. Therefore, the checking unit 606 knows which region of data in the memory device 601 needs to be kept (refreshed) during the low power mode (i.e., the self refresh mode), and then decides a memory maintenance map (e.g., flags) accordingly. Similarly, after the flags for indicating if the corresponding physical row partitions should be refreshed are set, the refresh control unit 608 controls the refresh operation of the memory device 601 according to the flags.

The refresh operation will be performed after the memory maintenance map of valid data needed to be kept (refreshed) is obtained. However, if a new memory allocation is performed before the refresh operation is performed according to the memory maintenance map, the memory maintenance map might be changed due to the fact that the new memory allocation might change the memory usage map. Therefore, the checking unit 606 has to check the memory maintenance map again, which degrades the performance of the overall system. To solve this problem, one implementation of the present invention guarantees that either no new memory allocation is performed, or the new memory allocation is allocated without changing the memory maintenance map.

In above exemplary implementation, the checking unit 606 in the memory control system 600 is configured for assigning an indicator (e.g., a flag) to each physical row partition determined by the determining unit 602 for indicating if the corresponding physical row partition should be refreshed. However, this merely serves as one of the possible implementations of the present invention. In an alternative design, the afore-mentioned memory maintenance map can be simply realized using a single flag (bit). Take the bank interleaving result shown in FIG. 7 as an example. In this alternative embodiment, the memory device 601 is a DRAM device to which only the single ended PASR scheme is available. For example, either a full array mode or a ½ array mode is enabled when the DRAM device is self-refreshed using the single ended PASR scheme. Besides, in this alternative embodiment, the flag F2 shown in FIG. 6 is omitted, and the memory maintenance map is therefore implemented using the flag F1 only. If the checking unit 606 refers to a memory usage map of a deeply embedded system or information maintained by an operating system to know that the memory device 601 only has valid data stored in virtual rows addressed by (Bank 0, Row 0), (Bank 0, Row 1), (Bank 0, Row 2) and (Bank 0, Row 3), the checking unit 606 sets the memory maintenance map (e.g., the single flag F1 in the alternative design) to indicate that the ½ array PASR should be enabled to refresh data stored in the physical row partition P1, where the other physical row partition P2 is not required to be refreshed during the low power mode due to the characteristics of the ½ array PASR. On the other hand, if the checking unit 606 refers to the derived memory usage map to know that the memory device 601 has valid data stored in the physical row partition P1 as well as the physical row partition P2, the checking unit 606 sets the memory maintenance map (e.g., the single flag F1 in this alternative design) to indicate that the full array refresh should be enabled to refresh valid data stored in both physical row partitions P1 and P2. To put it simply, the single flag is asserted/deasserted to indicate whether the partial refresh, such as the ½ array PASR, should be enabled.

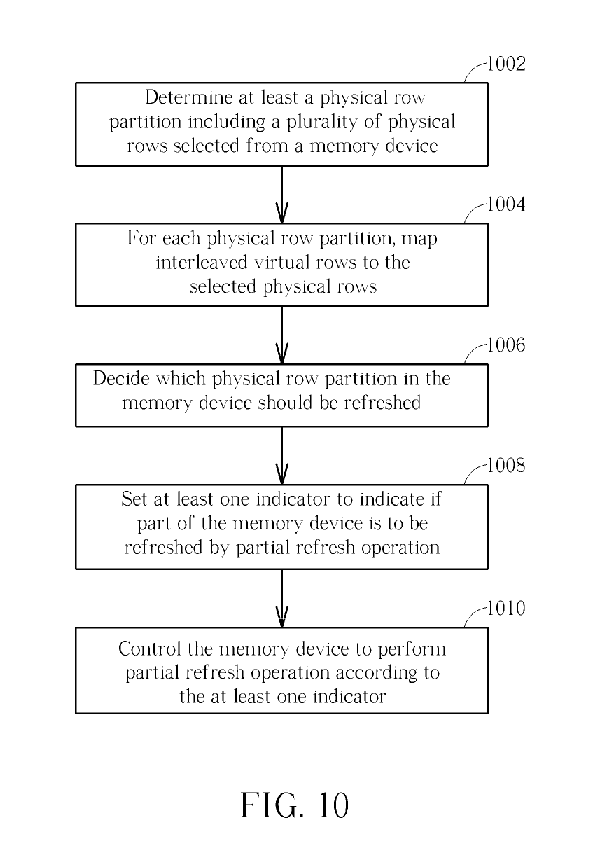

In view of above description, an exemplary memory control method employed by the memory control system 600 shown in FIG. 6 to perform the partition-based partial bank interleaving can be briefly summarized using following steps: determining at least a physical row partition including a plurality of physical rows selected from the memory device, wherein each physical row partition is a portion of the memory device; and for each physical row partition, mapping interleaved virtual rows to the selected physical rows, wherein bank addresses of adjacent virtual rows are different. In addition, an exemplary memory control method employed by the memory control system 600 shown in FIG. 6 to control a refresh operation of the memory device 601 can be briefly summarized using following steps: assigning an indicator to each physical row partition in the memory device for indicating if the corresponding physical row partition is to be refreshed, wherein each physical row partition is a portion of the memory device; and controlling a refresh operation of the memory device according to the indicator of each physical row partition. FIG. 10 is a flowchart illustrating a generalized memory control method of a memory device according to an exemplary embodiment of the present invention. Please note that if the result is substantially the same, the steps are not required to be executed in the exact order shown in FIG. 10. The flow of the memory control method includes following steps:

Step 1002: Determine at least a physical row partition including a plurality of physical rows selected from a memory device (e.g., a DRAM device), wherein each physical row partition is a portion of the memory device.

Step 1004: For each physical row partition, map interleaved virtual rows to the selected physical rows, wherein bank addresses of adjacent virtual rows are different.

Step 1006: Decide which physical row partition in the memory device should be refreshed.

Step 1008: Set at least one indicator to indicate if part of the memory device is to be refreshed by a partial refresh operation. For example, in one exemplary implementation, an indicator (e.g., a flag) is assigned to each physical row partition in the memory device for indicating if the corresponding physical row partition should be refreshed; in another exemplary implementation, only a single indicator (e.g., a single flag) is implemented to indicate if a partial refresh, such as ½ array PASR, should be enabled.

Step 1010: Control the memory device to perform the partial refresh operation (e.g., single ended PASR, dual ended PASR, or bank selective PASR) according to the at least one indicator (e.g., the afore-mentioned indicator of each physical row partition in the memory device or the afore-mentioned single indicator).

As a person skilled in the pertinent art could readily understand operations of the steps included in the flow show in FIG. 10 after reading above paragraphs directed to operations of the memory control system 600 shown in FIG. 6, further description is omitted here for the sake of brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory control method of a memory device, comprising:
setting at least one indicator to indicate if part of the memory device is to be refreshed by a partial refresh operation; and
controlling the memory device to perform the partial refresh operation according to the at least one indicator.

2. The memory control method of claim 1, wherein:
setting the at least one indicator to indicate if part of the memory device is to be refreshed by the partial refresh operation comprises:
assigning an indicator to each physical row partition in the memory device for indicating if the corresponding physical row partition is to be refreshed, wherein each physical row partition is a portion of the memory device; and
controlling the memory device to perform the partial refresh operation according to the at least one indicator comprises:
controlling the memory device to perform the partial refresh operation according to the indicator of each physical row partition.

3. The memory control method of claim 2, wherein assigning the indicator to each physical row partition in the memory device comprises:
deciding which physical row partition in the memory device is to be refreshed by the partial refresh operation to generate a checking result; and
setting the indicator assigned to each physical row partition according to the checking result.

4. The memory control method of claim 3, wherein deciding which physical row partition in the memory device is to be refreshed comprises:
determining a free physical memory map of the memory device to decide which physical row partition is to be refreshed.

5. The memory control method of claim 4, wherein determining the free physical memory map of the memory device comprises:
referring to information maintained by an operating system to determine the free physical memory map.

6. The memory control method of claim 1, further comprising:
mapping interleaved virtual rows to physical rows in the memory device.

7. The memory control method of claim 6, further comprising:
determining at least a physical row partition including a plurality of physical rows selected from the memory device, wherein each physical row partition is a portion of the memory device; and
for each physical row partition, mapping interleaved virtual rows to the selected physical rows, wherein bank addresses of adjacent virtual rows are different.

8. The memory control method of claim 7, wherein each of bank addresses of the interleaved virtual rows is selected from bank addresses of the selected physical rows.

9. The memory control method of claim 8, wherein the bank addresses of the selected physical rows correspond to consecutive physical banks of the memory device.

10. The memory control method of claim 8, wherein the bank addresses of the selected physical rows correspond to non-consecutive physical banks of the memory device.

11. The memory control method of claim 7, wherein bank addresses of the interleaved virtual rows include at least one bank address different from bank addresses of the selected physical rows.

12. A memory control system of a memory device, comprising:
a checking unit, configured for setting at least one indicator to indicate if part of the memory device is to be refreshed by a partial refresh operation; and
a refresh control unit, configured for controlling the memory device to perform the partial refresh operation according to the at least one indicator.

13. The memory control system of claim 12, wherein the checking unit assigns an indicator to each physical row partition in the memory device for indicating if the corresponding physical row partition is to be refreshed, where each physical row partition is a portion of the memory device; and the refresh control unit controls the memory device to perform the partial refresh operation according to the indicator of each physical row partition.

14. The memory control system of claim 13, wherein the checking unit decides which physical row partition in the memory device is to be refreshed by the partial refresh operation to generate a checking result, and sets the indicator assigned to each physical row partition according to the checking result.

15. The memory control system of claim 14, wherein the checking unit determines a free physical memory map of the memory device to decide which physical row partition is to be refreshed.

16. The memory control system of claim 15, wherein the checking unit refers to information maintained by an operating system to determine the free physical memory map.

17. The memory control system of claim 13, further comprising:
a determining unit, determining at least a physical row partition including a plurality of physical rows selected from the memory device, wherein each physical row partition is a portion of the memory device; and
a mapping unit, for each physical row partition, mapping interleaved virtual rows to the selected physical rows, wherein bank addresses of adjacent virtual rows are different.

18. The memory control system of claim 17, wherein each of bank addresses of the interleaved virtual rows is selected from bank addresses of the selected physical rows.

19. The memory control system of claim 18, wherein the bank addresses of the selected physical rows correspond to consecutive or non-consecutive physical banks of the memory device.

20. The memory control system of claim 17, wherein bank addresses of the interleaved virtual rows include at least one bank address different from bank addresses of the selected physical rows.
